(19) United States
(12) Patent Application Publication
(10) Pub. No.: US 2009/0159121 A1
(43) Pub. Date: Jun. 25, 2009

(54) CONDUCTIVE NANOPARTICLE INKS AND PASTES AND APPLICATIONS USING THE SAME

(75) Inventors: Zhihao Yang, Vestal, NY (US); Zhiyong Xu, Endicott, NY (US); Zeqi Tang, Vestal, NY (US)

Correspondence Address: FOLEY AND LARDNER LLP;SUITE 500, 3000 K STREET NW, WASHINGTON, DC, 20007, US

(73) Assignee: NanoMas Technologies, Inc.

(21) Appl. No.: 12/247,998

(22) Filed: Oct. 8, 2008

Related U.S. Application Data
(60) Provisional application No. 60/978,655, filed on Oct. 9, 2007.

(51) Int. Cl. H01L 31/042; B05D 5/12; B32B 15/00

(52) U.S. Cl. 136/256; 427/98.4; 428/450; 428/323; 438/674

(57) ABSTRACT

A method of fabricating a device, comprising a ink or paste on a silicon based semiconductor material, wherein the ink or paste comprises a mixture of inorganic conductive and additive nanoparticles and wherein the semiconductor material is silicon. An example is a mixture of silver and palladium nanoparticles.

### RELATED APPLICATIONS

This application claims priority to U.S. provisional patent application 60/978,655 filed Oct. 9, 2007.

### BACKGROUND

New and better nanostructured materials are needed for various applications in diverse industries, including and not limited to biotechnology, diagnostics, energy, and electronics. For example, electronics manufacturers are continually striving to decrease costs and increase functionality of electronic devices and components. One emerging strategy for cost reduction is directly printing electronics onto low-cost plastic films using solution-based inks. The so called Printed Electronics refers to the technologies of manufacturing functional electronic devices using the processes that have been used in the printing industry, such ink-jet printing, gravure printing, screen printing, flexographic printing, off-set printing, etc. in a high through-put and low-cost reel-to-reel (R2R) fashion. One example of the printed electronics is to construct electrical circuits using inkjet printing of patterns of metal nanoparticles to form conductors. This process is discussed in, for example, “Applications of Printing Technology in Organic Electronics and Display Fabrication”, by V. Subramanian, presented at the Half Moon Bay Maskless Lithography Workshop, DARPA/SRC, Half Moon Bay, CA, Nov 9-10, 2000.

Nanoparticle materials can differ from their larger-sized counterparts in their properties. For example, one of the most characteristic features of nanoparticles is the size-dependent surface melting point depression. (Ph. Buffat et al.; “Size effect on the melting temperature of gold particles” Physical Review A, Volume 13, Number 6, June 1976, pages 2287-2297; A. N. Goldstein et al.; “Melting in Semiconductor Nanocrystals” Science, Volume 256, Jun. 5, 2002, pages 1425-1427; and K. K. Nanda et al.; “Liquid-drop model for the size-dependent melting of low-dimensional systems” Physical Review, A 66 (2002), pages 013208-1 thru 013208-8.) This property enables the melting or sintering of the metal nanoparticles into polycrystalline films with good electric conductivity at a relatively low temperature.

Conductive metallic nanoparticle inks and pastes are one of the most important ingredient materials for the printed electronics devices. Among these, the silver nanoparticle inks and pastes become the most widely used in the electronics applications. However, one problem arises in applying these particle inks and pastes in the electronic devices made of silicon, which is the main component of currently about 98% of the commercial photovoltaic devices. Of these devices, 90% were made on crystalline silicon wafers (either single crystalline silicon (sc-Si) or multi-crystalline silicon (mc-Si) wafers) and 8% on amorphous silicon. Good Ohmic contact (i.e., low electrical resistance contact) in some cases can only be obtained upon thermally annealing silver on silicon based semiconductor materials at a temperature about 800° C. (see for example Kontermann et al.; “Investigations on the influence of different annealing steps on silicon solar cells with silver thick film contacts” 22^{nd} European Photovoltaic Solar Energy Conference and Exhibition, 3; September 2007, Milan, Italy.) It is well known to those familiar with the art that low-resistance, stable contacts are important and in some cases critical for the performance and reliability of integrated circuits (ICs) and their preparation and characterization are major efforts in circuit fabrication. However, heat treatment at high temperature can severely damage, if not completely destroy, the performance of the silicon based devices, such as CMOS circuits, amorphous silicon TFTs, nano-crystalline silicon devices, photovoltaic cells on n-type wafers, amorphous silicon thin film photovoltaic devices, and any printed electronics devices on plastic substrates.

In the majority of industrial crystalline silicon PV production process, the front electrodes are made by screen printing of silver paste on the surface of the wafers, followed by a thermal step comprising a heating to above about 800° C. As a result, 95% commercial PV cells are made from either sc-Si or p-type mc-Si wafers because the PV cells made from n-type mc-Si as well as amorphous silicon do not survive such high temperature treatment. The high temperature can destroy the p-n junctions in the PV cells, thereby disabling the functionality of the PV devices. There are emerging evidences that the n-type Czochralski mc-Si as materials for the PV devices is electronically superior to the p-type materials.

A need thus exists to fabricate, for example, a silicon based device that allows the annealing process to take place at a lower temperature, for example, preferably lower than about 500° C., and more preferably lower than about 300° C.

### SUMMARY

Provided herein are articles, compositions, methods of making, and methods of using.

In one embodiment, a method of fabricating a device, comprising a ink or paste disposed on a silicon based semiconductor material, wherein the ink or paste comprises a mixture of inorganic conductive and additive nanoparticles and wherein the semiconductor material is silicon.

Another embodiment provides a device, comprising: an ink or paste disposed on a semiconductor material; wherein the ink or paste comprises first conductive nanoparticles and further comprises second additive nanoparticles different from the first nanoparticles.

Another embodiment provides a device, comprising: at least two inks or pastes disposed on a semiconductor material; wherein the first ink or paste comprises first conductive nanoparticles, and the second ink or paste comprises second nanoparticles different from the first nanoparticles; and wherein the second nanoparticles are disposed between the semiconductor material and the first conductive nanoparticles.

In another embodiment, a method comprising: (a) providing a first mixture comprising at least one nanoparticle precursor and at least one first solvent for the nanoparticle precursor, wherein the nanoparticle precursor comprises a salt comprising a cation comprising a metal; (b) providing a second mixture comprising at least one reactive moiety reactive for the nanoparticle precursor and at least one second solvent for the reactive moiety, wherein the second solvent phase separates when it is mixed with the first solvent; and (c) combining said first and second mixtures in the presence of a surface stabilizing agent, wherein upon combination the first and second mixtures phase-separate and nanoparticles are formed. (d) formulating the nanoparticles into an ink or paste. (e) forming a film with the ink or paste on a silicon substrate.

Other methods can be used to prepare the nanoparticles.

At least one advantage is that an intermediate adhesion layer is not needed between the nanoparticles and the silicon. Another advantage in one or more embodiments is lower temperature processing. Another advantage in one or more embodiments is versatility in selecting nanoparticle composition and size.

### DETAILED DESCRIPTION

U.S. provisional application Ser. No. 60/791,325 filed on Apr. 12, 2006 and U.S. non-provisional application Ser. No. 11/734,692 filed on Apr. 12, 2007 are hereby incorporated by reference in their entirety.

In addition, U.S. priority provisional application Ser. No. 60/978,655 filed Oct. 9, 2007 is also hereby incorporated by reference in its entirety.

Further technology description for printed electronics can be found in for example Printed Organic and Molecular Electronics, edited by D. Gamota et al. (Kulwer, 2004).

Semiconductor materials and substrates including silicon materials and substrates are generally known in the art.

The present invention comprises in one embodiment a conductive ink or paste on a silicon-based semiconductor material. The ink or paste comprises a mixture of discrete inorganic nanoparticles synthesized by a multiphase-solution-based method. This method allows fabrication of discrete particles with size in the nanometer range and with a low melting temperature; a detailed description of this method is provided in Ser. No. 11/734,692. Other methods for fabrication of particles and nanoparticles can be used. The said ink or paste mixture comprises at least one highly conductive nanoparticulate material, such as silver, gold, copper, and aluminum, and at least one additive nanoparticulate material, such as palladium, nickel, titanium, and aluminum, that can help reduce the electrical contact resistance between the ink or paste and the silicon semiconductor material. The size of these conductive and additive particles generally ranges from 1 to 1000 nm, preferably from 1 to 100 nm, more preferably from 1 to 20 nm.

The semiconductor material in the invention can be silicon. The type of silicon can be, but not limited to, single crystalline silicon, multi-crystalline silicon, nano-crystalline silicon, and amorphous silicon.

Ink and paste formulations comprising nanoparticles are known in the art. One skilled in the art can adapt the concentration of the nanoparticles. For example, nanoparticles can be present in a weight percentage such as, for example, 10-50 wt. %, or 20-30 wt. %. A second different nanoparticle type can be included as an additive in relatively low amounts compared to the first nanoparticle type, for example, 10 wt. % or less, or 1 wt. % or less, or 0.1 wt. % or less, or 0.01 wt. % or less.

In the main embodiment of this invention the conductive ink or paste can be processed by inkjet printing, gravure printing, flexographic printing, and screen printing. Also, the said conductive ink or paste of this invention can be processed at a temperature less than about 500° C., and more preferably less than about 300° C. Annealing methods are generally known in the art, and articles and devices can be characterized prior to or post annealing.

Over 95% of all the solar cells produced worldwide are composed of the semiconductor material silicon (Si). As the second most abundant element in the crust of the Earth, silicon has the advantage, of being available in sufficient quantities, and additionally processing the material does not burden the environment. To produce a solar cell, the semiconductor is contaminated or “doped”. “Doping” is the intentional introduction of chemical elements, with which one can obtain a surplus of either positive charge carriers (p-conducting semiconductor layer) or negative charge carriers (n-conducting semiconductor layer) from the semiconductor material. If two differently contaminated semiconductor layers are combined, then a so-called p-n-junction results on the boundary of the layers. Ohmic metal-semiconductor contacts are made to both the n-type and p-type sides of the solar cell, and the electrodes connected to an external load.

Solar cell efficiencies vary from 6% for amorphous silicon-based solar cells to 40.7% with multiple-junction research lab cells and 42.8% with multiple dies assembled into a hybrid package. Solar cell energy conversion efficiencies for commercially available multicrystalline Si solar cells are around 14-19%. While there are many factors that can affect the efficiency of solar cells, the Ohmic metal-semiconductor contacts is one important factor. Generally, silver or aluminum is used for making metal contacts so that the current can be harnessed from solar energy. Screen-printing can be used to add a layer of these conducting metals onto the surface of the wafer in a certain pattern. Screen-printing can work by first having a screen with open areas for the locations at which the metal is applied. A paste or ink containing a mixture of conducting metal, organic solvents, and organic binders can be put on one end of the screen with the wafer underneath. A squeegee can be used to facilitate transporting the conducting mixture from one end of the screen to the other. As the squeegee pushes the mixture, the mixture can fall into the gaps of the screen, thereby being applied to the wafer. Subsequently, the wafer can be heated to evaporate the organics, thereby leaving the metal contacts on the wafer. This process can be applied to the back and/or the front of the wafer. Silver can be used as a n-type material and aluminum as a p-type.

It is generally known in the art that silver can be an excellent conductor for electricity and can make an excellent contact for semiconductor devices. Thus, in one embodiment, the front and/or back contacts for solar cells can be advantageously formed at least in part from silver so that, particularly in the case of a front contact, a body of silver can extend in the form of a grid across the front face of the cell. The cell can be any type, such as p-1-n type or p-n type. The cell also can be a photovoltaic cell. This grid can collect electrons that have been formed by the cell when the front surface thereof is exposed to light. These electrons can then migrate to the silver metal contact and be conducted by the silver grid across the front surface of the cell to bussbars or other suitable methods for directing the electrons away from the cell. A back contact for solar cells can serve a complementary function, and it need not extend in any particular pattern across the back surface of the cell that is not exposed to light. The back contact can generally operate to close the electrical circuit arising at least in part from the impingement of light on the front surface of the cell.

Silver has been a preferred contact-forming material for solar cells and other semiconductor devices. However, good metal-to semiconductor Ohmic contacts between silver and silicon in most cases can only be obtained upon thermally annealing silver on silicon based semiconductor materials at a temperature at least about 800° C. (see for example Kontermann et al.; “Investigations on the influence of different annealing steps on silicon solar cells with silver thick film contacts” 22^{nd} European Photovoltaic Solar Energy Conference and Exhibition, 3; September 2007, Milan, Italy.).

U.S. Pat. No. 4,082,568 to Lindmayer discloses a method of having titanium and palladium layers between the silver metal contact and the silicon semiconductor by vacuum vapor deposition to improve contact between the metal and semiconductor without the high temperature step (above 500° C.) to treat the solar cells. One embodiment herein discloses a method of using a conductive ink or paste to form the metal contact in photovoltaic devices. The conductive ink or paste can comprise a mixture of discrete inorganic nanoparticles synthesized by a multiphase-solution-based method. This method can allow fabrication of discrete particles with size in the nanometer range and with a low melting temperature; a detailed description of this method is provided in Ser. No. 11/734,692, which is herein incorporated by reference in its entirety. In one embodiment, the ink or paste mixture can comprise at least one highly conductive nanoparticulate material, such as silver, gold, copper, and aluminum, and at least one additive nanoparticulate material, such as palladium, platinum, nickel, titanium, molybdenum and aluminum. The additive nanoparticulate material (or “nanoparticles”) can help reduce the contact electrical resistance between the ink or paste and the silicon semiconductor material. The silicon semiconductor material can comprise for example single- or multi-crystalline silicon, or it can comprise amorphous silicon, or alternatively it can comprise micro- or nano-crystalline silicon. The size of these conductive and additive nanoparticles generally can range from 1 to 1000 nm, preferably from 1 to 100 nm, more preferably from 1 to 20 nm.

The open-circuit voltage, V_{oc}, is the maximum voltage available from a solar cell, and this occurs at zero current. The open-circuit voltage corresponds to the amount of forward bias on the solar cell due to the bias of the solar cell junction with the light-generated current. An equation for V_{oc} can be found by setting the net current equal to zero in the solar cell equation to give:

$${V}_{OC} = \frac{nkT}{q} ln ( \frac{{I}_{L}}{{I}_{0}} + 1 )$$

The above equation shows that V_{oc} depends on the saturation current of the solar cell and the light-generated current. The saturation current, I₀, can depend on recombination in the solar cell and can vary by orders of magnitude. Hence, open-circuit voltage can be a measure of the amount of recombination in the device. For example, silicon solar cells with high quality single crystalline material have open-circuit voltages of up to 730 mV under one sun and AM1.5 conditions, while commercial devices with multicrystalline silicon generally can have open-circuit voltages of around 600 mV. Many factors can affect the measured open-circuit voltage of a solar cell, and the metal to semiconductor contact resist can be an important one.

The use of additional nanoparticles as described herein can result in an increase in open circuit voltage of, for example, at least 100%, or at least 200%, or at least 300%, or at least 400%, as illustrated for example below. An open circuit voltage can be, for example, at least 100 mV, or at least 200 mV, or at least 300 mV, or at least 400 mV, or at least 500 mV, or at least 577 mV.

Articles can be described both in the pre-annealing state and the post-annealing state.

Additional embodiments are provided in the following non-limiting working examples.

### Example 1

### Synthesis of Metal Nanoparticles

The metal nanoparticles were synthesized with the method disclosed in U.S. patent application Ser. No. 11/734,692.

### Synthesis of Silver (Ag) Nanoparticles:

3.34 grams of silver acetate and 37.1 grams of dodecylamine were dissolved in 400 ml of toluene (in a 1000 ml 3-neck reaction flask) and heated to 60° C. for the silver acetate completely dissolved. The water bath temperature was subsqeutnyl reduced to 30° C. 1.51 grams of sodium borohydride (NaBH₄) was dissolved in 150 ml of water. The NaBH₄ solution was added drop-wise into the reaction flask through a dropping funnel over a period of 5 min. The solution was stirred during the reaction for about 2.5 hours before the stirring stopped. The solution settled into two phases (dark red-brown in the top toluene phase and clear in the bottom water phase). The water phase was removed by a separation funnel, and toluene was subsequently removed from the solution by evaporation with a rotor evaporator, resulting in a highly viscous dark paste. 250 ml of 50/50 methanol/acetone was added to precipitate the silver nanoparticles. The solution was filtrated through a fine sintered glass funnel, and the solid product was collected and vacuum dried at room temperature. Deep blue solid powders were obtained. The nanoparticles have the size of 4-5 nm, as examined by TEM.

### Synthesis of Palladium (Pd) Nanoparticles:

4.49 grams (20 mM) palladium acetate (PdAc) (99.9% from Sigma-Aldrich) and 18.53 grams (100 mM) of dodecylamine (Sigma-Aldrich) were dissolved in 1500 ml toluene in a reactor with mechanical stirring. 3.03 grams (80 mM) of Sodium borohydride (NaBH₄) were dissolved in 300 ml de-ionized (DI) water. Fresh NaBH₄ solution was added into PdAc solution drop-wise while the solution was continuously stirred. The solution was stirred for another 2 hours until the reaction was completed. The solution would settled into two phases: dark brown in the top toluene phase and clear in the bottom water phase. The water phase was then removed by using a separation funnel, and the oil phase containing palladium nanoparticles was collected in a round bottom flask. Toluene was removed from the oil toluene phase by using a rotor evaporator, resulting in a viscous dark paste containing highly concentrated palladium nanoparticles and surfactants. 1800 ml of 50/50 Ethanol/Acetone solution was added to the paste to precipitate the palladium nanoparticles. The solution was filtered by using a filter funnel and the solid product of nanoparticles was collected and vacuum dried at room temperature. Dark solid powders were obtained. The nanoparticles have the size of 5-7 nm examined by TEM.

### Example 2

### Printed Metal Contact on Silicon Photovoltaic Devices

Commercial grade multi-crystalline silicon solar cell wafers were obtained from a commercial solar cell manufacturer. The wafers were fabricated with the standard p-type silicon solar cell processes, except without deposit of the anti-reflection coating and the top metal contacts. These commercial devices typically have open-circuit voltages at about 600 mV. A series of nanoparticle inks comprising silver nanoparticles and palladium nanoparticles were printed by ink jet printing on the solar cell wafers, thereby being in contact with the n-doped silicon. A line resolution of about 50 to about 100 microns can be achieved. The printed top electrodes were annealed at 200° C. on a hotplate for 10 minutes. In one sample, a first layer of Pd nanoparticle ink was printed as the direct contact layer and the sample was annealed at 350° C. for 10 minutes. Subsequently, a second layer of Ag nanoparticle ink was printed on top of the first layer of Pd, and the sample was annealed again at 200° C. for 10 minutes. The open circuit voltages of the cells were measured under a standard commercially available solar simulator (Sun-2000-6) at a standard radiation intensity of 135.3 mW/cm². The results of the samples tested with different nanoparticle ink compositions and their corresponding measured solar cell open-circuit voltages are listed in Table 1.

TABLE 1

| Samples | Ink Compositions | Voc (mV) |
|---|---|---|
| A.(control): | 25% wt pure silver nanoparticle ink | 66 |
| B: | 25% wt silver nanoparticle ink with | 441 |
| | 0.01% palladium nanoparticles | |
| C | 25% wt silver nanoparticle ink with | 457 |
| | 0.1% palladium nanoparticles | |
| D | 25% wt silver nanoparticle ink with | 572 |
| | 1% palladium nanoparticles | |
| E | 7% wt palladium nanoparticle ink as | 577 |
| | contact layer and 35% wt pure silver | |
| | nanoparticle ink as top layer | |

As shown in Table 1, in one embodiment, the device made by printing with pure silver nanoparticles inks had a poor electrical contact between the highly conductive metal nanoparticulate material and the silicon solar cell, resulting in a very low open-circuit voltage. However, the addition of a small amount as additive nanoparticulate material, such as Pd nanoparticles, reduced the electrical contact resistance between the highly conductive metal nanoparticulate material and the silicon semiconductor material, thereby improving the open-circuit voltage. For example, adding only about 1% Pd nanoparticles into the Ag nanoparticle inks resulted in the overall sample showing almost ohmic contact with the silicon semiconductor material, as over 95% of cell open-circuit voltage can be achieved. In alternative embodiments, the highly conductive metal nanoparticulate material can be silver, gold, copper, aluminum, or a combination thereof, and the additive nanoparticulate material can be palladium, platinum, nickel, titanium, molybdenum, aluminum, or a combination thereof. The additive nanoparticulate material that can help reduce the electrical contact resistance between the ink or paste and the silicon semiconductor material. The size of these conductive and additive particles can range from 1 to 1000 nm, preferably from 1 to 100 nm, more preferably from 1 to 20 nm.

Alternatively, the additive nanoparticulate material can be printed separately from the highly conductive metal nanoparticulate material. In one embodiment, a layer comprising the additive nanoparticulate material was first printed with a silicon semiconductor material with good electric contact. Subsequently, a layer comprising the highly conductive metal nanoparticulate material is printed on top of the layer comprising the additive nanoparticulate material.

### Example 3

### Measurements of Contact Resistance of Printed Nanoparticle Inks or Pastes on Silicon Semiconductor

Contact resistance was measured using the Transmission Line Method (TLM): A series of contact pads (0.3×3 mm) were printed by ink jet printing on a test grade (As)-doped n-type Si (100) wafer (0.013−0.004 ohm-cm) purchased from University Wafer. The wafers were cut to 4×30 mm and surface treated with a 7% HF solution before printing. The gaps between the contacts ranged from 2 mm to 20 mm. Two inks of nanoparticles were used for comparison: (A) 25% wt pure silver nanoparticle ink (control), and (B) 25% wt nanoparticle ink of silver/palladium nanoparticles with a 10:1 weight ratio.

The samples were annealed at 250° C. for 3 minutes. The resistances between the pads for each sample was measured under a constant current of 100 mA. The specific contact resistances were deduced, using the TLM method, to be about 110 mω-cm² and 6 mω-cm², from samples A and B, respectively. In one embodiment, it was observed that using palladium nanoparticles as the additive nanoparticles in the inks of silver conductive nanoparticles significantly reduces the contact resistance with the silicon semiconductor material.

### EMBODIMENTS

The following 42 embodiments were also described in priority to U.S. provisional patent application 60/978,655 filed Oct. 9, 2007.

1. A method comprising:
(a) providing a first mixture comprising at least one nanoparticle precursor and at least one first solvent for the nanoparticle precursor, wherein the nanoparticle precursor comprises a salt comprising a cation comprising a metal;
(b) providing a second mixture comprising at least one reactive moiety reactive for the nanoparticle precursor and at least one second solvent for the reactive moiety, wherein the second solvent phase separates when it is mixed with the first solvent; and
(c) combining said first and second mixtures in the presence of a surface stabilizing agent, wherein upon combination the first and second mixtures phase-separate and nanoparticles are formed.
(d) formulating the nanoparticles into an ink or paste.
(e) forming a film with the ink or paste on a silicon substrate.

2. The method according to embodiment 1, wherein the first solvent comprises an organic solvent, and the second solvent comprises water.

3. The method according to embodiment 1, wherein the first solvent comprises a hydrocarbon solvent, and the second solvent comprises water.

4. The method according to embodiment 1, wherein the nanoparticles comprise silver.

5. The method according to embodiment 1, wherein the reactive moiety comprises a reducing agent.

6. The method according to embodiment 1, wherein the reactive moiety comprises a hydride.

7. The method according to embodiment 1, wherein the reactive moiety comprises a hydroxyl producing agent.

8. The method according to embodiment 1, wherein the surface stabilizing agent, the first solvent, and the second solvent, are adapted so that when the first and second solvents phase separate and form an interface, the surface stabilizing agent migrates to the interface.

9. The method according to embodiment 1, wherein the surface stabilizing agent comprises at least one alkylene group and a nitrogen atom or an oxygen atom.

10. The method according to embodiment 1, wherein the surface stabilizing agent comprises at least substituted amine or substituted carboxylic acid, wherein the substituted group comprise two to thirty carbon atoms.

11. The method according to embodiment 1, wherein the surface stabilizing agent comprises an amino compound, a carboxylic acid compound, or a thiol compound.

12. The method according to embodiment 1, wherein the surface stabilizing agent comprises an amino compound, or a carboxylic acid compound.

13. The method according to embodiment 1, wherein the first mixture comprises the surface stabilizing agent.

14. The method according to embodiment 1, wherein the first mixture comprises the surface stabilizing agent, and the second mixture is free of surface stabilizing agent.

15. The method according to embodiment 1, wherein the phase-separation produces an interface and the nanoparticles form at the interface.

16. The method according to embodiment 1, further comprising the step of collecting the nanoparticles, wherein the collected nanoparticles have an average particle size of about 1 nm to about 20 nm.

17. The method according to embodiment 1, further comprising the step of collecting the nanoparticles, wherein the collected nanoparticles have an average particle size of about 2 nm to about 10 nm, and the nanoparticles have a monodispersity showing standard deviation of 3 nm or less.

18. The method according to embodiment 1, wherein the nanoparticles can be formed into a film having electrical conductivity due to the material in the nanoparticles, or wherein the nanoparticles can be formed into a semiconductive film having semiconductivity due to the material in the nanoparticles, or wherein the nanoparticles can be formed into an electroluminescent film having electroluminescence due to the material in the nanoparticles.

19. The method according to embodiment 1, wherein the volume of the first mixture is greater than the volume of the second mixture.

20. The method according to embodiment 1, wherein the combination is carried out without external application of heat or cooling.

21. A device, comprising:

an ink or paste disposed on a semiconductor material;

wherein the ink or paste comprises first conductive nanoparticles and further comprises second additive nanoparticles different from the first nanoparticles.

22. The device according to embodiment 21, wherein the first conductive nanoparticles that are fabricated by the method according to steps (a) to (d) in embodiment 1.

23. The device according to embodiment 21, wherein the second additive nanoparticles are fabricated according to steps (a) to (d) in embodiment 1.

24. The device according to embodiment 21, wherein the conductive and additive particles are inorganic.

25. The device according to embodiment 21, wherein the conductive nanoparticles are silver.

26. The device according to embodiment 21, where the conductive nanoparticle particle size is less than about 1 micron.

27. The device according to embodiment 21, where the conductive nanoparticle particle size is about 1 nm to about 100 nm.

28. The device according to embodiment 21, where the conductive nanoparticle particle size is about 1 nm to about 20 nm.

29. The device according to embodiment 21, where the additive nanoparticles are palladium.

30. The device according to embodiment 21, where the additive nanoparticle particle size is less than 1 micron.

31. The device according to embodiment 21, wherein the material is single crystalline silicon.

32. The device according to embodiment 21, wherein the material is multi-crystalline silicon.

33. The device according to embodiment 21, wherein the material is nano-crystalline silicon.

34. The device according to embodiment 21, wherein the material is amorphous silicon.

35. The device according to embodiment 21, wherein the first and second nanoparticles are processed by inkjet printing.

36. The device according to embodiment 21, wherein the first and second nanoparticles are processed by gravure printing.

37. The device according to embodiment 21, wherein the first and second nanoparticles are processed by flexographic printing.

38. The device according to embodiment 21, wherein the first and second nanoparticles are processed by screen printing.

39. The device according to embodiment 21, wherein the first and second nanoparticles are processed at a temperature less than about 500° C.

40. The device according to embodiment 21, wherein the first and second nanoparticles are processed at a temperature less than about 300° C.

41. The device according to embodiment 21, wherein the first nanoparticles are silver, gold, or copper nanoparticles.

42. The device according to embodiment 21, wherein the second nanoparticles are palladium, nickel, titanium, or aluminum nanoparticles.

What is claimed:

1. A method comprising:
(a) providing a first mixture comprising at least one nanoparticle precursor and at least one first solvent for the nanoparticle precursor, wherein the nanoparticle precursor comprises a salt comprising a cation comprising a metal;
(b) providing a second mixture comprising at least one reactive moiety reactive for the nanoparticle precursor and at least one second solvent for the reactive moiety, wherein the second solvent phase separates when it is mixed with the first solvent; and
(c) combining said first and second mixtures in the presence of a surface stabilizing agent, wherein upon combination the first and second mixtures phase-separate and nanoparticles are formed.
(d) formulating the nanoparticles into an ink or paste.
(e) forming a film with the ink or paste on a silicon substrate.

2. The method according to claim 1, wherein the first solvent comprises an organic solvent, and the second solvent comprises water.

3. The method according to claim 1, wherein the first solvent comprises a hydrocarbon solvent, and the second solvent comprises water.

4. The method according to claim 1, wherein the nanoparticles comprise silver.

5. The method according to claim 1, wherein the reactive moiety comprises a reducing agent.

6. The method according to claim 1, wherein the second additive nanoparticles reduce the contact electrical resistance between the semiconductor material and the first conductive nanoparticles after the step (e).

7. The method according to claim 1, wherein the reactive moiety comprises a hydroxyl producing agent.

8. The method according to claim 1, wherein the surface stabilizing agent, the first solvent, and the second solvent, are adapted so that when the first and second solvents phase separate and form an interface, the surface stabilizing agent migrates to the interface.

9. The method according to claim 1, wherein the surface stabilizing agent comprises at least one alkylene group and a nitrogen atom or an oxygen atom.

10. The method according to claim 1, wherein the surface stabilizing agent comprises at least substituted amine or substituted carboxylic acid, wherein the substituted group comprise two to thirty carbon atoms.

11. The method according to claim 1, wherein the surface stabilizing agent comprises an amino compound, a carboxylic acid compound, or a thiol compound.

12. The method according to claim 1, wherein the surface stabilizing agent comprises an amino compound, or a carboxylic acid compound.

13. The method according to claim 1, wherein the first mixture comprises the surface stabilizing agent.

14. The method according to claim 1, wherein the first mixture comprises the surface stabilizing agent, and the second mixture is free of surface stabilizing agent.

15. The method according to claim 1, wherein the phase-separation produces an interface and the nanoparticles form at the interface.

16. The method according to claim 1, further comprising the step of collecting the nanoparticles, wherein the collected nanoparticles have an average particle size of about 1 nm to about 20 nm.

17. The method according to claim 1, further comprising the step of collecting the nanoparticles, wherein the collected nanoparticles have an average particle size of about 2 nm to about 10 nm, and the nanoparticles have a monodispersity showing standard deviation of 3 nm or less.

18. The method according to claim 1, wherein the nanoparticles can be formed into a film having electrical conductivity due to the material in the nanoparticles, or wherein the nanoparticles can be formed into a semiconductive film having semiconductivity due to the material in the nanoparticles, or wherein the nanoparticles can be formed into an electroluminescent film having electroluminescence due to the material in the nanoparticles.

19. The method according to claim 1, wherein the volume of the first mixture is greater than the volume of the second mixture.

20. The method according to claim 1, wherein the combination is carried out without external application of heat or cooling.

21. A device, comprising:
an ink or paste disposed on a semiconductor material;
wherein the ink or paste comprises first conductive nanoparticles and further comprises second additive nanoparticles different from the first nanoparticles.

22. The device according to claim 21, wherein the first conductive nanoparticles that are fabricated by the method according to steps (a) to (d) in claim 1.

23. The device according to claim 21, wherein the second additive nanoparticles are fabricated according to steps (a) to (d) in claim 1.

24. The device according to claim 21, wherein the conductive and additive particles are inorganic.

25. The device according to claim 21, wherein the conductive nanoparticles are silver.

26. The device according to claim 21, where the conductive nanoparticle particle size is less than about 1 micron.

27. The device according to claim 21, where the conductive nanoparticle particle size is about 1 nm to about 100 nm.

28. The device according to claim 21, where the conductive nanoparticle particle size is about 1 nm to about 20 nm.

29. The device according to claim 21, where the additive nanoparticles are palladium.

30. The device according to claim 21, where the additive nanoparticle particle size is less than 1 micron.

31. The device according to claim 21, wherein the material is single crystalline silicon.

32. The device according to claim 21, wherein the material is multi-crystalline silicon.

33. The device according to claim 21, wherein the material is nano-crystalline silicon.

34. The device according to claim 21, wherein the material is amorphous silicon.

35. The device according to claim 21, wherein the first and second nanoparticles are processed by inkjet printing.

36. The device according to claim 21, wherein the first and second nanoparticles are processed by gravure printing.

37. The device according to claim 21, wherein the first and second nanoparticles are processed by flexographic printing.

38. The device according to claim 21, wherein the first and second nanoparticles are processed by screen printing.

39. The device according to claim 21, wherein the first and second nanoparticles are processed at a temperature less than about 500° C.

40. The device according to claim 21, wherein the first and second nanoparticles are processed at a temperature less than about 300° C.

41. The device according to claim 21, wherein the first nanoparticles are silver, gold, or copper nanoparticles, or combinations thereof.

42. The device according to claim 21, wherein the second nanoparticles are palladium, nickel, titanium, or aluminum nanoparticles, or combinations thereof.

43. The device according to claim 21, is a photovoltaic device.

44. The device according to claim 21, wherein the first conductive nanoparticles are more electrically conductive than the second additive nanoparticles.

45. A device, comprising:
at least two inks or pastes disposed on a semiconductor material;
wherein the first ink or paste comprises first conductive nanoparticles, and the second ink or paste comprises second nanoparticles different from the first nanoparticles; and
wherein the second nanoparticles are disposed between the semiconductor material and the first conductive nanoparticles.

46. The device according to claim 45, wherein the first conductive nanoparticles are more electrically conductive than the second nanoparticles.

47. The device according to claim 45, wherein the second nanoparticles reduce the contact electrical resistance between the semiconductor material and the first conductive nanoparticles.

48. The device according to claim 45, wherein the first nanoparticles are silver, gold, or copper nanoparticles, or combinations thereof.

49. The device according to claim 45, wherein the second nanoparticles are palladium, nickel, titanium, or aluminum nanoparticles, or combinations thereof.

50. The device according to claim 45, wherein the semiconductor material comprises silicon.

51. The device according to claim 45, wherein the device is annealed.

52. The device according to claim 45, wherein the device is not yet annealed.
